(19) United States
(12) Patent Application Publication
(10) Pub. No.: US 2023/0178579 A1
(43) Pub. Date: Jun. 8, 2023

(54) LIGHT RECEIVING ELEMENT AND ELECTRONIC DEVICE

(71) Applicant: SONY SEMICONDUCTOR SOLUTIONS CORPORATION, KANAGAWA (JP)

(72) Inventors: MAKOTO OONO, KUMAMOTO (JP); TAKANORI TADA, KUMAMOTO (JP); KENJI TOSHIMA, KUMAMOTO (JP)

(21) Appl. No.: 17/906,682

(22) PCT Filed: Feb. 8, 2021
(86) PCT No.: PCT/JP2021/004520

§ 371 Date: Sep. 19, 2022

(30) Foreign Application Priority Data
Mar. 31, 2020 (JP) 2020-065336

(51) Int. Cl. H01L 27/146; G01S 7/4865; G01S 7/4915; G01S 17/08; G01S 17/89

(52) U.S. Cl. CPC H01L 27/14636; H01L 27/14649; H01L 27/14634; G01S 7/4865; G01S 7/4915; G01S 17/08; G01S 17/89

(57) ABSTRACT

To prevent the occurrence of poor connection between an electrode pad and a bonding wire.

A light receiving element includes a wiring region, an electrode pad, a first recessed portion, and a second recessed portion. The wiring region is disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light. The electrode pad is disposed in the wiring region and is connected to the wiring layer so as to be connected to the outside. The first recessed portion is formed on the back side of the semiconductor substrate and has the bottom near the front side of the semiconductor substrate and near the electrode pad. The second recessed portion is formed at the bottom of the first recessed portion and has the bottom formed on a surface of the electrode pad.

### TECHNICAL FIELD

The present disclosure relates to a light receiving element and an electronic device. Specifically, the present disclosure relates to a light receiving element that detects light from an object and an electronic device in which the light receiving element is used.

### BACKGROUND ART

Conventionally, a light receiving element in which a plurality of pixels are placed is used, the pixel including a photoelectric conversion unit that detects light from an object. The light receiving element is used for, for example, a ranging device that measures a distance to an object. A distance to an object can be measured by irradiating the object with light from an attached light source, detecting light reflected from the object, and measuring the time for the light from the light source to reciprocate between the object and the light source. Such a light receiving element used for measuring a distance to an object needs to detect light with high sensitivity at high speeds. Used as a photoelectric conversion unit is an avalanche photo diode (APD) or a single photon avalanche diode (SPAD), which is a kind of photodiode. These diodes are photodiodes that perform photoelectric conversion while a reverse bias voltage close to a breakdown voltage is applied. These diodes enable high-speed response with high sensitivity.

A photodetector is used as the light receiving element. The photodetector includes, for example, an APD disposed as a photoelectric conversion unit in a pixel, a separation region that separates adjacent pixels, and a hall storage region on a side wall of the separating region (e.g., see PTL 1). Electrons emitted from an interface state formed on the end face of a semiconductor substrate at pixel borders are captured by the hall storage region, thereby reducing dark current caused by electrons from the interface state. Here, the dark current is a current based on charges generated irrespective of incident light and is the cause of a signal output error (noise).

In the foregoing photodetector, a signal from the APD is transmitted to the outside via an electrode pad. The electrode pad is disposed in a wiring layer adjacent to the front side of the semiconductor substrate, in which the APD is disposed, and is placed at the bottom of a pad opening formed from the back side of the semiconductor substrate. Wire bonding is performed through the pad opening, and then a bonding wire is connected to the electrode pad. The signal of the electrode pad can be transmitted to an external electronic circuit or the like via the bonding wire.

### CITATION LIST

### Patent Literature

### [PTL 1]

JP 2018-201005 A

### SUMMARY

### Technical Problem

Unfortunately, the foregoing technique may cause poor connection between the electrode pad and the bonding wire. In order to improve the sensitivity, the photoelectric conversion unit is formed on the semiconductor substrate having a relatively large thickness. In the use of distance measurement, infrared light is used and the photoelectric conversion unit receives infrared light. Since long-wave infrared light reaches a relatively deep region of the semiconductor substrate, the semiconductor substrate having a large thickness is used. The semiconductor substrate having a large thickness has a deep pad opening. This leads to difficulty in forming the pad opening, increasing the probability of occurrence of a fault. Specifically, an etching residue may occur on the surface of the electrode pad at the bottom of the pad opening. Moreover, a reaction product generated by etching may be deposited near the bottom of the pad opening without being discharged. In this case, the deposited reaction product may corrode the electrode pad. These faults may cause poor connection between the electrode pad and the bonding wire.

The present disclosure was devised in view of the above-described problems. An object of the present disclosure is to prevent the occurrence of poor connection between an electrode pad and a bonding wire.

### Solution to Problem

The present disclosure has been devised to solve the problems. A first aspect of the present disclosure is a light receiving element including: a wiring region disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light; an electrode pad that is disposed in the wiring region and is connected to the wiring layer so as to be electrically connected to the outside; a first recessed portion that is formed on the back side of the semiconductor substrate, the back side being opposed to the front side of the semiconductor substrate, the first recessed portion having the bottom near the front side of the semiconductor substrate and near the electrode pad; and a second recessed portion that is formed on the front side of the first recessed portion and has the bottom formed on a surface of the electrode pad.

In the first aspect, the second recessed portion may be configured with a different opening size from the first recessed portion.

In the first aspect, on the back side of the semiconductor substrate, the second recessed portion may have a different opening area from the first recessed portion in plan view.

In the first aspect, on the front side of the semiconductor substrate, the second recessed portion may have a different opening area from the first recessed portion in plan view.

In the first aspect, the second recessed portion may have an opening area and a bottom area that are different from each other.

In the first aspect, the second recessed portion may have a larger shape on the back side of the semiconductor substrate than on the bottom side of the second recessed portion.

In the first aspect, the second recessed portion may be tapered in cross section.

In the first aspect, the second recessed portion may have a plurality of tapered shapes with different tilt angles in cross section.

In the first aspect, the first recessed portion may have an opening area and a bottom area that are different from each other.

In the first aspect, the first recessed portion may have a larger shape on the back side of the semiconductor substrate than on the bottom side of the first recessed portion.

In the first aspect, the first recessed portion may be tapered in cross section.

In the first aspect, the first recessed portion may be configured with a vertical wall surface.

In the first aspect, the first recessed portion may be configured with a curved side.

In the first aspect, the first recessed portion may have a bottom linearly shaped in cross section.

In the first aspect, the first recessed portion may be configured with a curved bottom.

In the first aspect, a reaction product may be deposited in the first recessed portion during etching.

In the first aspect, the photoelectric conversion unit may include a photodiode.

In the first aspect, the photoelectric conversion unit may include the photodiode that multiplies, by a high reverse bias voltage, a charge generated by the photoelectric conversion of incident light.

In the first aspect, the photoelectric conversion unit may allow the multiplication on the generated charge at a pn junction including a p-type semiconductor region and an n-type semiconductor region.

In the first aspect, the photoelectric conversion unit may have a cathode region including the n-type semiconductor region.

In the first aspect, the photoelectric conversion unit may have the cathode region disposed on the front side of the semiconductor substrate.

In the first aspect, the photoelectric conversion unit may have an anode region disposed on the front side of the semiconductor substrate.

A second aspect of the present disclosure is a light receiving element including: a wiring region disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light; an electrode pad that is disposed in the wiring region and is connected to the wiring layer so as to be electrically connected to the outside; a first recessed portion that is formed on the back side of the semiconductor substrate and has the bottom not so deep as to reach the electrode pad; and a second recessed portion configured with the bottom reaching the electrode pad from the bottom of the first recessed portion.

A third aspect of the present disclosure is a light receiving element including: a wiring region disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light; an electrode pad that is disposed in the wiring region and is connected to the wiring layer so as to be electrically connected to the outside; a first recessed portion that is formed on the back side of the semiconductor substrate, the back side being opposed to the front side of the semiconductor substrate, the first recessed portion having the bottom near the front side of the semiconductor substrate and near the electrode pad; a second recessed portion that is formed on the front side of the first recessed portion and has the bottom formed on a surface of the electrode pad; and a processing circuit that processes a signal generated on the basis of the photoelectric conversion.

In the third aspect, the photoelectric conversion unit may perform photoelectric conversion on the incident light that is emitted from a light source, is reflected from a subject, and enters the photoelectric conversion unit, and the processing circuit may perform the processing of measuring a distance to the subject by measuring a time from the light emission from the light source to the generation of the signal.

In the third aspect, the processing circuit may perform the processing of detecting a change of the signal.

In the third aspect, the processing circuit may detect the change by comparison with a predetermined threshold value.

In the third aspect, the processing circuit may be disposed on another semiconductor substrate bonded to the semiconductor substrate.

According to the aspects of the present disclosure, the electrode pad is opened on the back side of the semiconductor substrate by the first recessed portion and the second recessed portion. It is assumed that the electrode pad is opened on the back side of the semiconductor substrate by the two steps of forming the recessed portions.

### BRIEF DESCRIPTION OF DRAWINGS

FIG. 1 is a diagram illustrating a configuration example of a light receiving element according to a first embodiment of the present disclosure.

FIG. 2 is a diagram illustrating a configuration example of a pixel according to the first embodiment of the present disclosure.

FIG. 3 is a cross-sectional view illustrating a configuration example of the pixel according to the first embodiment of the present disclosure.

FIG. 4 is a cross-sectional view illustrating another configuration example of the pixel according to the first embodiment of the present disclosure.

FIG. 5 is a plan view illustrating a configuration example of a pad opening according to the first embodiment of the present disclosure.

FIG. 6 is a cross-sectional view illustrating a configuration example of the pad opening according to the first embodiment of the present disclosure.

FIG. 7 is a cross-sectional view illustrating a comparison example of the configuration of the pad opening.

FIG. 8 is a diagram illustrating an example of a method of manufacturing the pad opening according to the first embodiment of the present disclosure.

FIG. 9 is a diagram illustrating the example of the method of manufacturing the pad opening according to the first embodiment of the present disclosure.

FIG. 10 is a cross-sectional view illustrating a configuration example of a pad opening according to a second embodiment of the present disclosure.

FIG. 11 is a cross-sectional view illustrating another configuration example of the pad opening according to the second embodiment of the present disclosure.

FIG. 12 is a cross-sectional view illustrating another configuration example of the pad opening according to the second embodiment of the present disclosure.

FIG. 13 is a cross-sectional view illustrating a configuration example of a pixel according to a third embodiment of the present disclosure.

FIG. 14 is a diagram illustrating a configuration example of a light receiving element for a ranging device to which the technique according to the present disclosure is applicable.

FIG. 15 is a circuit diagram illustrating a configuration example of the pixel for the ranging device to which the technique according to the present disclosure is applicable.

FIG. 16 is a diagram illustrating a configuration example of an imaging device for the ranging device to which the technique according to the present disclosure is applicable.

FIG. 17 is a diagram illustrating a configuration example of the light receiving element for a DVS to which the technique according to the present disclosure is applicable.

FIG. 18 is a diagram illustrating a configuration example of the pixel for a DVS to which the technique according to the present disclosure is applicable.

FIG. 19 is a diagram illustrating a configuration example of a current-voltage conversion circuit for a DVS to which the technique according to the present disclosure is applicable.

FIG. 20 is a diagram illustrating a configuration example of a differential device and a quantizer for a DVS to which the technique according to the present disclosure is applicable.

FIG. 21 is a diagram illustrating a configuration example of the imaging device for a DVS to which the technique according to the present disclosure is applicable.

### DESCRIPTION OF EMBODIMENTS

Modes for implementing the present disclosure (hereinafter referred to as embodiments) will be described below with reference to the drawings. In the following drawings, the same or similar portions are denoted by the same or similar reference numerals and signs. In addition, the embodiments will be described in the following order.

### 1. First Embodiment

### 2. Second Embodiment

### 3. Third Embodiment

4. Example of application to ranging device
5. Example of application to DVS

### 1. First Embodiment

### [Configuration of Light Receiving Element]

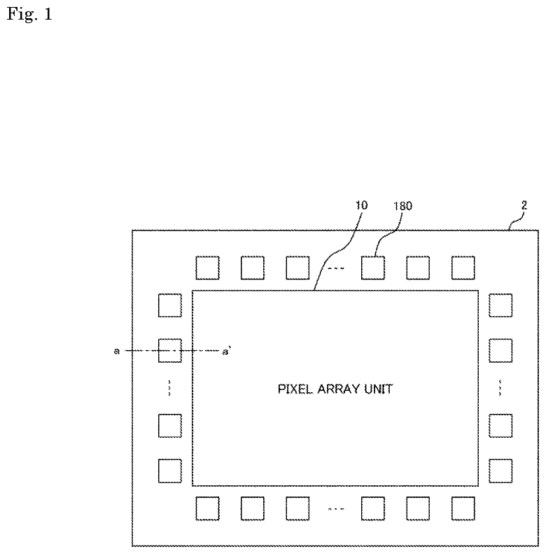

FIG. 1 is a diagram illustrating a configuration example of a light receiving element according to a first embodiment of the present disclosure. FIG. 1 is a plan view illustrating a configuration example of a light receiving element 2. The plan view illustrates the configuration of a light receiving surface irradiated with incident light of the light receiving element 2.

A pixel array unit 10 is disposed on the light receiving surface of the light receiving element 2. The pixel array unit 10 is a region that is disposed at the central portion of the light receiving element 2 and includes pixels (pixels 100 described later) for detecting incident light, the pixels being disposed in a two-dimensional lattice form. In the pixel 100, a photoelectric conversion unit (a photoelectric conversion unit 101 described later) for photoelectric conversion of incident light is disposed. A received light signal is generated according to charge generated by the photoelectric conversion of the photoelectric conversion unit 101 and is outputted from the pixel 100. The received light signal allows the detection of incident light. A plurality of pad openings 180 are disposed on the ends of the light receiving element 2. At the bottom of the pad opening 180, an electrode pad (electrode pads 128 and 148 described later) is disposed. As will be described later, the light receiving element 2 is configured with two semiconductor chips bonded to each other.

### [Pixel Configuration]

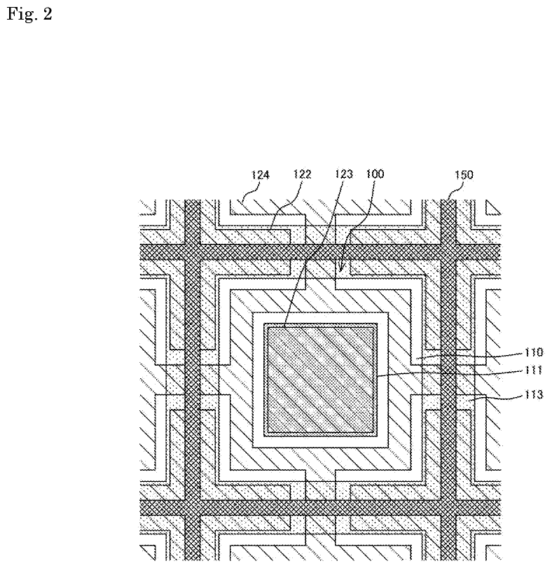

FIG. 2 is a diagram illustrating a configuration example of the pixel according to the first embodiment of the present disclosure. FIG. 2 is a plan view illustrating a configuration example of the pixel 100. Illustrated in the pixel 100 of FIG. 2 are semiconductor regions (semiconductor regions 111 and 113) formed on a semiconductor substrate 110, a separation region 150 that is disposed at the borders of the pixel 100 and is configured like a wall penetrating the semiconductor substrate 110, and wiring layers 122 to 124. In FIG. 2, a region with dot hatching denotes the semiconductor region 111 or the like while a region with diagonal hatching denotes the wiring layer 122 or the like.

The semiconductor region 111 is disposed at the central portion of the pixel 100 and constitutes a cathode region. The semiconductor regions 113 are disposed at the circumferential edge of the pixel 100 and constitute an anode region. The wiring layer 122 constitutes anode wiring and is connected to the semiconductor regions 113. The wiring layer 123 constitutes cathode wiring and is connected to the semiconductor region 111. The wiring layer 124 is a ground wire for a shield. The shield suppresses the influence of electrical noise. The wiring layer 124 is disposed in a region between the wiring layers 122 and 123.

### [Configuration of Pixel in Cross Section]

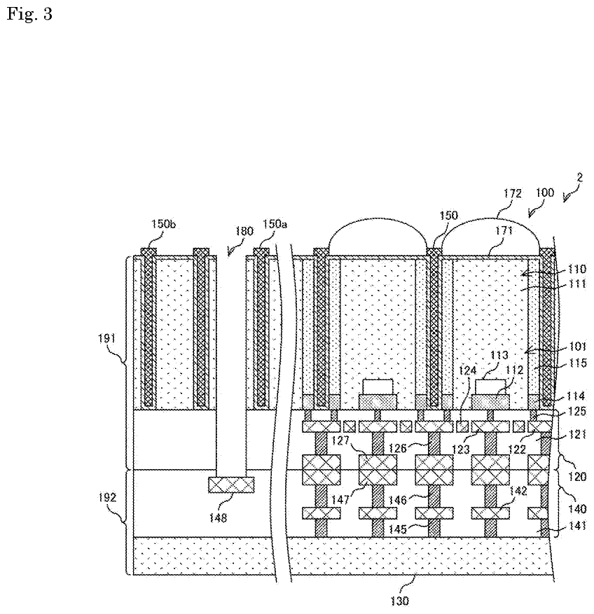

FIG. 3 is a cross-sectional view illustrating the configuration example of the pixel according to the first embodiment of the present disclosure. FIG. 3 is a cross-sectional view that is taken along line a-a′ of FIG. 1 and illustrates a configuration example of the light receiving element 2 and the pixels 100. As illustrated in FIG. 3, the light receiving element 2 is configured with a sensor chip 191 and a logic chip 192 bonded to each other. The sensor chip 191 is a semiconductor chip in which the photoelectric conversion units 101 are disposed. The photoelectric conversion unit 101 will be described later. The logic chip 192 is a semiconductor chip in which a processing circuit is disposed to process a signal generated by the photoelectric conversion unit 101.

The pixel 100 in FIG. 3 includes the semiconductor substrate 110, a wiring region 120, a semiconductor substrate 130, a wiring region 140, the separation region 150, a protective film 171, and an on-chip lens 172. The semiconductor substrate 110, an insulating layer 121, and the wiring layers 122 to 124 are disposed in the sensor chip 191. The semiconductor substrate 130, an insulating layer 141, and a wiling layer 142 are disposed in the logic chip 192.

The semiconductor substrate 110 is a semiconductor substrate in which the photoelectric conversion unit 101 for photoelectric conversion of incident light is disposed. For example, a semiconductor substrate made of silicon (Si) can be used as the semiconductor substrate 110. The photoelectric conversion unit 101 in FIG. 3 is an example of an SPAD configuration. The photoelectric conversion unit 101 includes a well region 111 of the semiconductor substrate 110, an n-type semiconductor region 112 disposed in the well region 111, the p-type semiconductor region 113, and a semiconductor region 114. The n-type semiconductor region 112 constituting the cathode region constitutes a pn junction with the p-type semiconductor region 113. A reverse bias voltage is applied to the pn junction through the well region 111, forming a depletion layer.

Photoelectric conversion by the photoelectric conversion unit 101 of FIG. 3 is performed in the well region 111. When electrons of charge generated by a photoelectric effect reach the depletion layer of the pn junction because of drift, the electrons are accelerated by an electric field based on a reverse bias voltage. A reverse bias voltage exceeding a breakdown voltage is applied to the photoelectric conversion unit 101 constituting the SPAD. Specifically, a reverse bias voltage of about 20 V is applied. An intense electric field generated by the reverse bias voltage causes consecutive electron avalanches, thereby rapidly increasing a charge. Thus, the photoelectric conversion unit 101 can detect the entry of a single photon. The pixel 100 can be configured with high sensitivity by disposing the photoelectric conversion unit 101 configured thus. A region near the pn junction of the interface between the semiconductor regions 112 and the 113 is a region where a charge is multiplied. The region is referred to as a multiplication region. The p-type semiconductor region 114 is disposed next to the well region 111 and constitutes the anode region. The p-type semiconductor region 114 is configured to surround the well region 111 near the n-type semiconductor region 112.

The semiconductor substrate 110 is configured with a relatively large thickness. This configuration is aimed at improving the sensitivity of the photoelectric conversion unit 101 with a large thickness of the well region 111 constituting the SPAD. For example, the semiconductor substrate 110 can be configured with a thickness of several μm. The well region 111 is disposed on the back side of the semiconductor substrate 110, and incident light enters from the back of the semiconductor substrate 110. The back of the semiconductor substrate 110 is equivalent to a light incident surface. On the front of the semiconductor substrate 110, that is, a surface opposed to the back, the wiring region 120 is disposed. The wiring region 120 will be described later. The semiconductor regions 112 and 114 constituting the cathode region and the anode region, respectively, are disposed on the front side of the semiconductor substrate 110.

The configuration of the photoelectric conversion unit 101 is not limited to this example. For example, the conductivity types of the semiconductor regions 112, 113, and 114 may be exchanged with one another. Specifically, the p-type semiconductor region 112 and the n-type semiconductor regions 113 and 114 may be used. In this case, the semiconductor region 112 serves as an anode region while the semiconductor region 114 serves as a cathode region. Furthermore, a hall storage region 115, which will be described later, is changed to an electron storage region 115. The electron storage region 115 is a region that includes an n-type semiconductor and stores electrons. The conductivity types of the semiconductor regions may be denoted as a first conductivity type and a second conductivity type instead of the p-type and the n-type.

The hall storage region 115 can be disposed in the semiconductor substrate 110 adjacent to the separation region 150, which will be described later. The hall storage region 115 is provided to capture electrons emitted from the interface state formed on the end face of the semiconductor substrate. The hall storage region 115 can be configured using a p-type semiconductor region. Electrons from the interface state are captured by recombination with halls stored in the hall storage region 115. Dark current caused by electrons from the interface state can be reduced by disposing the hall storage region 115. Moreover, acceleration and multiplication of electrons from the interface state may cause a malfunction. The occurrence of a dark current and a malfunction can be prevented by disposing the hall storage region 115. The hall storage region 115 in FIG. 3 is disposed next to the semiconductor region 114 constituting an anode and is electrically connected to the anode. Another hall storage region may be disposed at an interface on the back side of the semiconductor substrate 110.

The wiring region 120 is a region that is disposed on the front side of the semiconductor substrate 110 and includes wirings for transmitting signals to the photoelectric conversion unit 101 or the like. In the wiring region 120, the insulating layer 121 and the wiring layers 122 to 124 are disposed. The wiring layers 122 to 124 are wirings for transmitting a signal or the like of the photoelectric conversion unit 101. The wiring layer 122 or the like can be made of a metal such as copper (Cu). The insulating layer 121 insulates the wiring layer 122 or the like. The insulating layer 121 can be made of, for example, silicon oxide (SiO₂). The wiring region 120 further includes a contact plug 125 for connecting the semiconductor region of the semiconductor substrate 110 and the wiring layer 122. The wiring layer 122 is connected to the semiconductor region 114, which constitutes the anode region of the photoelectric conversion unit 101, via the contact plug 125. Likewise, the wiring layer 123 is connected to the semiconductor region 112 constituting the cathode region. The contact plug 125 can be made of, for example, tungsten (W).

The wiring region 120 further includes pads 127 and via plugs 126. The pads 127 are electrodes that are disposed at the front surface of the wiring region 120. The pads 127 can be made of, for example, Cu. The via plug 126 connects the wiring layer 122 or the like and the pad 127. The via plugs 126 can be made of, for example, Cu.

The semiconductor substrate 130 is a semiconductor substrate bonded to the semiconductor substrate 110. In the semiconductor substrate 130, a diffusion region can be formed for an element of a processing circuit or the like for processing a signal generated by the photoelectric conversion unit 101.

The wiring region 140 is a wiring region disposed on the front side of the semiconductor substrate 130. In the wiring region 140, the wiring layer 142 and the insulating layer 141 are disposed. On a surface of the wiring region 140, pads 147 are disposed and are connected to the wiring layer 142 by via plugs 146. The wiring layer 142 and the semiconductor substrate 130 are connected to each other via contact plugs 145. When the sensor chip 191 is bonded to the logic chip 192, the pads 147 and the pads 127 are bonded to each other. This electrically connects the pads 147 and 127. Signals can be transmitted and received between elements disposed in the semiconductor substrates 110 and 130 through the pads 147 and the pads 127. Wirings can be configured to connect the photoelectric conversion unit and the processing circuit. In this way, the wirings that electrically connect the photoelectric conversion unit 101 and the circuit can be disposed in the wiring regions 120 and 140. Moreover, the wiring regions 120 and 140 may include a wiring layer constituting an optical shield that reflects incident light having passed through the semiconductor substrate 110 and causes the light to enter the semiconductor substrate 110 again.

The separation region 150 is disposed in the semiconductor substrate 110 at the border between the pixels 100 and separates the photoelectric conversion units 101. The separation region 150 is configured like a wall surrounding the pixel 100 and separates the photoelectric conversion units 101 of the adjacent pixels 100. Furthermore, the separation region 150 blocks incident light. Incident light diagonally passing through the adjacent pixels 100 is blocked by the separation region 150. This can reduce the occurrence of crosstalk. As illustrated in FIG. 2, the separation region 150 is disposed in a lattice form. The separation region 150 can be configured with embedded metallic materials such as W or aluminum (Al) in grooves formed through the semiconductor substrate 110.

The protective film 171 is disposed on the back side of the semiconductor substrate 110 and protects the semiconductor substrate 110. This protective film 171 can be made of, for example, SiO₂.

Furthermore, a fixed charge film can be disposed between the semiconductor substrate 110 and the protective film 171. The fixed charge film is a film that is disposed on a surface of the semiconductor substrate 110 and has a fixed charge for pinning the interface state of the semiconductor substrate 110. The fixed charge film can be made of, for example, HfO₂.

The fixed charge film can be also disposed in the groove of the semiconductor substrate 110 with the separation region 150 disposed in the groove. Moreover, an insulating film that insulates the separation region 150 made of a metal can be disposed next to the separation region 150. The insulating film can be formed concurrently with the protective film 171.

The on-chip lens 172 is a lens that concentrates incident light. The on-chip lens 172 is configured in a hemispherical shape on the back side of the semiconductor substrate 110 and concentrates incident light onto the photoelectric conversion unit 101. The on-chip lens 172 can be made of an inorganic material such as silicon nitride (SiN) or an organic material such as acrylic resin.

On the end of the light receiving element 2, the electrode pad 148 and the pad opening 180 are disposed. The electrode pad 148 is an electrode for transmitting signals between the light receiving element 2 and an electronic circuit outside the light receiving element 2. The electrode pad 148 is disposed in the wiring region of the logic chip 192 and is connected to the wiring layer 142. The pad opening 180 is configured like a hole through the sensor chip 191 and the front side of the insulating layer 141 of the logic chip 192 and is shaped to reach the surface of the electrode pad 148 from the light receiving surface of the light receiving element 2. The electrode pad 148 is subjected to wire bonding through the pad opening 180, thereby electrically connecting the electrode pad 148 and the external electronic circuit. The electrode pad 148 can be made of, for example, a metal such as Al or

Au.

A separation region 150a can be disposed around the pad opening 180. The separation region 150a is configured to surround the pad opening 180 and separates the pad openings 180. Furthermore, a separation region 150b may be disposed in the semiconductor substrate 110 on the end of the sensor chip 191. The separation region 150b is a separation region disposed along the outer edge of the semiconductor substrate 110. The disposed separation regions 150a and 150b can prevent moisture absorption from the end face of the semiconductor substrate 110, thereby preventing an extension of a crack on the end face of the semiconductor substrate 110.

The configuration of the pixel 100 is not limited to this example. For example, a plurality of photoelectric conversion units may be disposed in the pixel 100. In the pixel 100 configured thus, the separation region that separates the photoelectric conversion units can be disposed therein. The separation region that separates the photoelectric conversion units can be formed through the semiconductor substrate 110. Furthermore, a separation region can be disposed between the semiconductor substrate 110 and the on-chip lens 172 at the border between the photoelectric conversion units. The separation region is a separation region that blocks light at the border between the photoelectric conversion units and can be composed of a metal film or the like. Alternatively, the pixel 100 including the photoelectric conversion units can be configured with a separation region disposed only at the border between the pixels 100. The hall storage region 115 can be also disposed on the back side of the semiconductor substrate 110.

### [Another Configuration of Cross Section of Pixel]

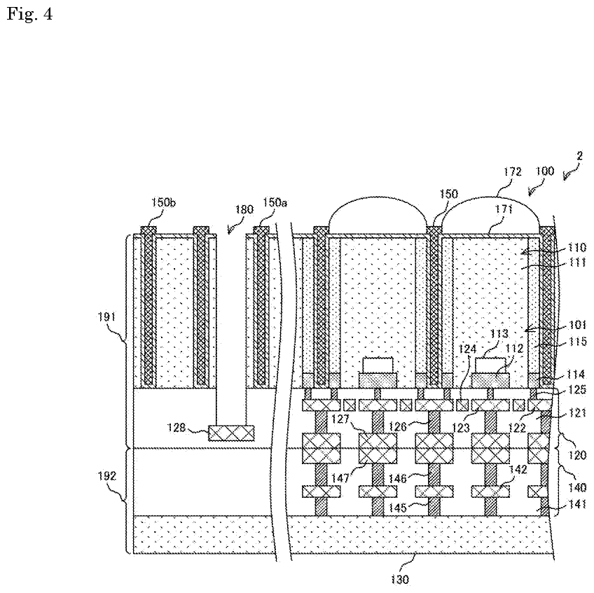

FIG. 4 is a cross-sectional view illustrating another configuration example of the pixel according to the first embodiment of the present disclosure. FIG. 4 is a cross-sectional view illustrating a configuration example of the pixel 100 as in FIG. 3. The pixel 100 is different from the pixel 100 in FIG. 3 in that an electrode pad 128 is disposed instead of the electrode pad 148. The electrode pad 128 is an electrode pad disposed in the wiring region 120 of the sensor chip 191 and is connected to the wiring layer of the wiring region 120 or the wiring layer of the wiring region 140 of the logic chip 192. The pad opening 180 in FIG. 4 is formed through the semiconductor substrate 110 of the sensor chip 191 and is shaped to reach the surface of the electrode pad 128 from the light receiving surface of the light receiving element 2.

### [Configuration of Pad Opening]

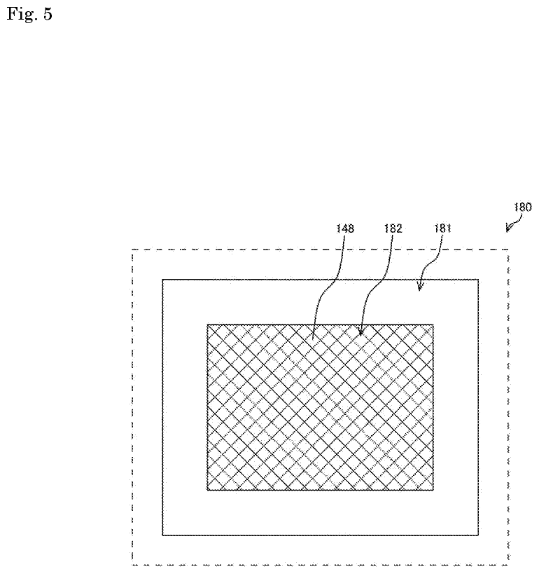

FIG. 5 is a plan view illustrating a configuration example of a pad opening according to the first embodiment of the present disclosure. FIG. 5 is a plan view illustrating a configuration example of the pad opening 180 illustrated in FIG. 3. Referring to FIG. 5, the configuration of the pad opening 180 will be specifically described below.

As described above, the pad opening 180 is an opening reaching the electrode pad 148 disposed in the wiring region 140 on the end of the light receiving element 2 and an opening created from the back side of the semiconductor substrate 110. A dotted-line rectangle in FIG. 5 indicates the outside shape of the electrode pad 148. The pad opening 180 in FIG. 5 includes a first recessed portion 181 and a second recessed portion 182 formed inside the first recessed portion 181. FIG. 5 illustrates an example of the electrode pad 148 and the pad opening 180 that are configured like rectangles.

### [Configuration of Pad Opening in Cross Section]

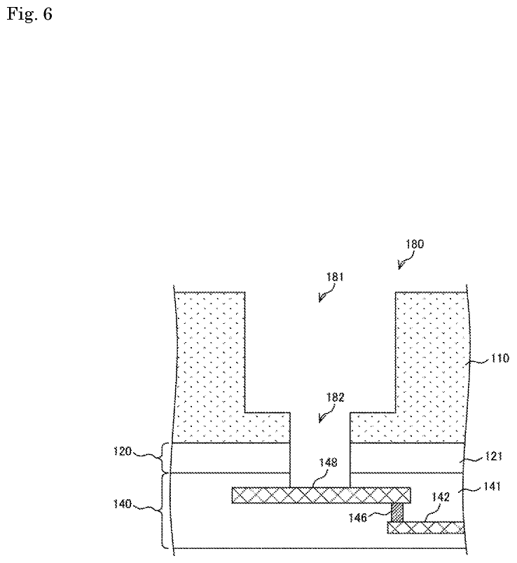

FIG. 6 is a cross-sectional view illustrating a configuration example of the pad opening according to the first embodiment of the present disclosure. The electrode pad 148 is disposed in the wiring region 140 disposed on the front side of the semiconductor substrate 130. As described above, the semiconductor substrate 110 and the semiconductor substrate 130 are bonded to each other. At this point, the wiring region 120 and the wiring region 140 are bonded to each other. As a result, the wiring region 140 is disposed on the front side of the semiconductor substrate 110. The electrode pad 148 is connected to the wiring layer 142 via the via plug 146. As illustrated in FIG. 3, the wiring layer 142 is connected to the wiring layer 122 or the like of the wiring region 120 via the pads 147 and 127 and is connected to the photoelectric conversion unit 101. The pad opening 180 includes the first recessed portion 181 and the second recessed portion 182.

The first recessed portion 181 is a recessed portion formed on the back side of the semiconductor substrate 110 near the electrode pad 148. The first recessed portion 181 is formed on the back side of the semiconductor substrate 110 and has the bottom near the front side of the semiconductor substrate 110. The first recessed portion 181 can be formed by etching the semiconductor substrate 110. For this etching, anisotropic dry etching can be used. The first recessed portion 181 has the bottom in the region of the semiconductor substrate 110, thereby protecting the wiring layer 142 near the electrode pad 148. FIG. 6 illustrates an example of the first recessed portion 181 configured with vertical wall surfaces. The first recessed portion 181 in FIG. 6 illustrates an example in which the bottom is linearly shaped in cross section.

The second recessed portion 182 is a recessed portion formed on the front side of the first recessed portion 181. The bottom of the second recessed portion 182 is formed on a surface of the electrode pad 148. In other words, the second recessed portion 182 is a recessed portion that is shaped to reach the electrode pad 148 from the bottom of the first recessed portion 181. The second recessed portion 182 can be configured with a different opening size from the first recessed portion 181. Specifically, the second recessed portion 182 can be configured with a smaller opening size than the first recessed portion 181. The second recessed portion 182 can be configured with a smaller opening size than the bottom of the first recessed portion 181. It can be also understood that the opening area of the second recessed portion 183 on the back side of the semiconductor substrate 110 is different from that of the first recessed portion 181 in plan view. It can be also understood that the opening area of the second recessed portion 183 on the front side of the semiconductor substrate 110 is different from that of the first recessed portion 181 in plan view. The second recessed portion 182 in FIG. 6 illustrates an example of the vertical wall surfaces.

The second recessed portion 182 can be formed by etching the semiconductor substrate 110 and the insulating layers 121 and 141. As described above, the pad opening 180 in FIG. 6 can be formed by two-step etching on the two recessed portions. Different etching conditions can be applied to the first recessed portion 181 and the second recessed portion 182. For example, when the second recessed portion 182 is formed, etching can be performed using etching gas different from that of the first recessed portion 181 and with power and a gas pressure upon ionization of etching gas.

It is to be understood that the configuration of the pad opening 180 in FIG. 6 is also applicable to the pixels 100 illustrated in FIG. 4. In this case, the electrode pad 128 is disposed at the bottom of the pad opening 180.

### [Comparison Example of Pad Opening]

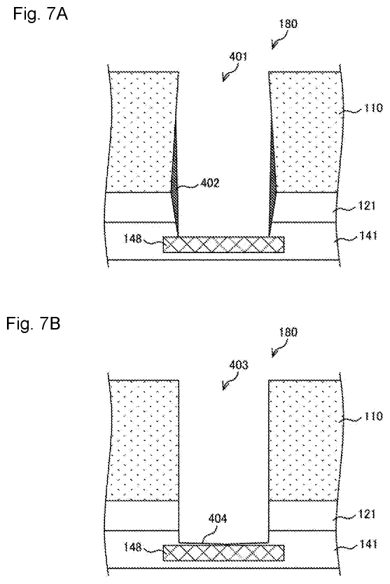

FIG. 7 is a cross-sectional view illustrating a comparison example of the configuration of the pad opening. FIG. 7 is a diagram illustrating an example of the pad opening 180 formed by single-step etching.

A in FIG. 7 indicates an example of the pad opening with a recessed portion 401 reversely tapered in cross section in the region of the semiconductor substrate 110. In dry etching for forming the recessed portion 401, Si and SiO₂ making up the semiconductor substrate 110 and the insulating layer 121, respectively, are successively etched. In this case, fluorocarbon gas is used as etching gas. Etching on SiO₂ with the etching gas generates a reaction product of a fluorine compound. If the semiconductor substrate 110 has a large thickness, the recessed portion 401 is relatively deep, so that the reaction product may be partially deposited on the wall surface of the recessed portion 401 without being discharged. Moreover, as illustrated in FIG. 7, the recessed portion 401 reversely tapered in cross section may increase reaction production on the side wall of the reversely tapered shape. A reaction product 402 in FIG. 7 indicates the deposited fluorine compound. Corrosion of the electrode pad 148 by the reaction product 402 may cause poor connection between the electrode pad and the bonding wire.

B in FIG. 7 indicates an example of a recessed portion 403 having a vertical shape in cross section. If the recessed portion 403 is relatively deep, the bottom is hard to etch, leaving an etching residue 404 on the surface of the electrode pad 148. The etching residue 404 may cause poor connection between the electrode pad 148 and the bonding wire.

As described above, the relatively deep pad opening 180 formed by single-step etching is likely to cause a fault.

### [Method of Manufacturing Pad Opening]

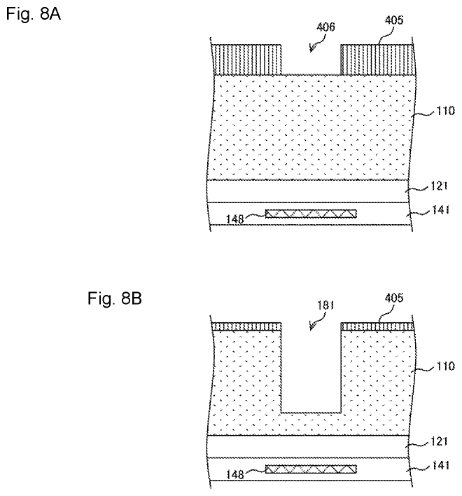

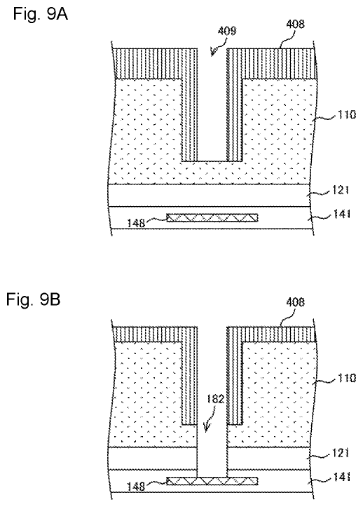

FIGS. 8 and 9 are diagrams illustrating an example of a method of manufacturing the pad opening according to the first embodiment of the present disclosure. FIGS. 8 and 9 are diagrams illustrating an example of a manufacturing process of the pad opening 180.

First, the semiconductor substrate 110 having the wiring region 120 and the semiconductor substrate 130 (not illustrated) having the wiring region 140 are bonded to each other to join the insulating layer 121 and the insulating layer 141. Subsequently, a resist 405 is disposed on the back side of the semiconductor substrate 110. In this resist 405, an opening 406 is disposed in a region where the first recessed portion 181 is to be formed (A in FIG. 8).

The semiconductor substrate 110 is then etched with the resist 405 serving as a mask. For this etching, dry etching can be used. Thus, a recessed portion 181 is formed (B in FIG. 8).

The resist 405 is then removed, and another resist 408 is disposed. In this resist 408, an opening 409 is disposed in a region where the second recessed portion 182 is to be formed (C in FIG. 9).

Etching is then performed using the resist 408 as a mask to form the second recessed portion 182 (D in FIG. 9). Thereafter, the resist 408 is removed, thereby producing the pad opening 180.

The configuration of the opening 180 is not limited to this example. For example, the opening 180 can be also configured with three or more recessed portions having different opening sizes. The shape of the first recessed portion 181 is not limited to this example. For example, the configuration may have curved sides.

In this configuration, the first recessed portion 181 and the second recessed portion 182 constitute the pad opening 180, thereby keeping the clean surface of the electrode pad 148. This can prevent the occurrence of poor connection between the electrode pad and the bonding wire during wire bonding.

### 2. Second Embodiment

In the light receiving element 2 of the first embodiment, the second recessed portion 182 having vertical wall surfaces is disposed. A light receiving element 2 according to a second embodiment of the present disclosure is different from that of the first embodiment in the use of a second recessed portion tapered in cross section.

### [Configuration of Pad Opening]

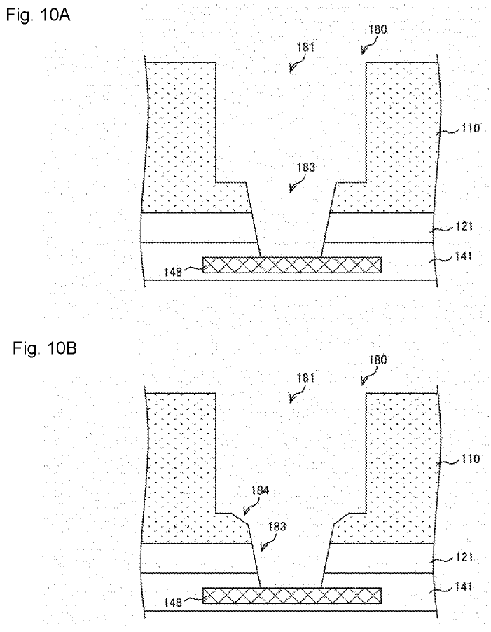

FIG. 10 is a cross-sectional view illustrating a configuration example of a pad opening according to the second embodiment of the present disclosure. FIG. 10 is a cross-sectional view illustrating a configuration example of a pad openings 180 as in FIG. 6. The configuration is different from the separation region 150 illustrated in FIG. 6 in that a second recessed portion 183 is disposed instead of the second recessed portion 182.

A in FIG. 10 indicates an example of the pad opening 180 including a first recessed portion 181 and the second recessed portion 183. The second recessed portion 183 is a recessed portion in which the opening and the bottom have different sizes. The second recessed portion 183 can be shaped such that the opening and the bottom have different areas. In this configuration, the opening area indicates the area of an opening on a surface of the back side of a semiconductor substrate 110 while the bottom area indicates, at the bottom of the recessed portion, the area of a surface parallel to the surface of the back side of the semiconductor substrate 110. For example, the second recessed portion 183 can be configured to have a large size on the back side of the semiconductor substrate 110 and a small size near an electrode pad 148. The second recessed portion 183 in FIG. 10 illustrates an example of a recessed portion tapered in cross section. The second recessed portion 183 forward tapered in cross section can reduce the deposition of a reaction product during etching.

B in FIG. 10 indicates an example of a plurality of second recessed portions that are tapered with different tilt angles in cross section. The pad opening 180 in B of FIG. 10 includes the first recessed portion 181, the second recessed portion 183, and a second recessed portion 184. The second recessed portion 184 is a recessed portion that is disposed next to the bottom of the first recessed portion 181 and is tapered with a smaller tilt angle than the second recessed portion 183 in cross section. The second recessed portion 184 is disposed between the first recessed portion 181 and the second recessed portion 183. This chamfers a part where the second recessed portion 183 is in contact with the bottom of the first recessed portion 181, thereby further reducing the deposition of a reaction product during etching.

The second recessed portions 183 and 184 in FIG. 10 can be formed by adjusting the shape of a resist.

### [Other Configurations of Pad Opening]

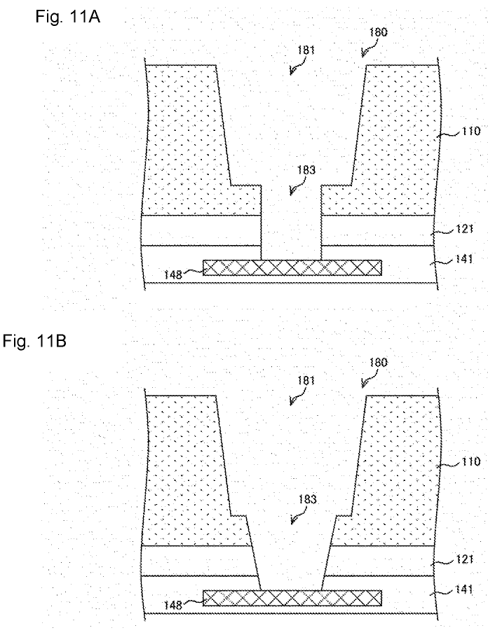

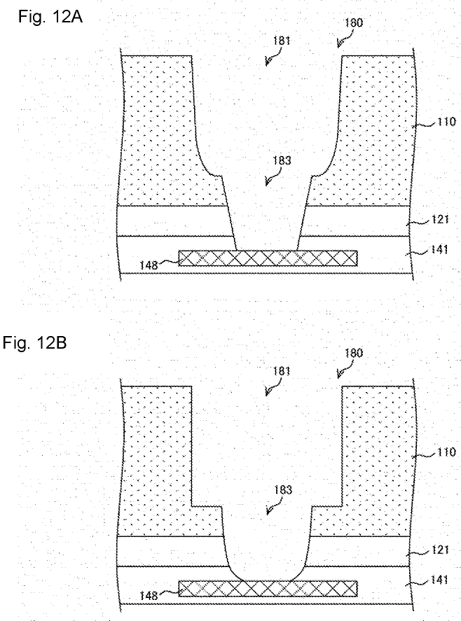

FIGS. 11 and 12 are cross-sectional views illustrating other configuration examples of the pad opening according to the second embodiment of the present disclosure. A in FIG. 11 indicates an example of the opening 180 including the first recessed portion 181 in a tapered shape and the second recessed portion 183 in which the opening and the bottom are substantially identical in size. B in FIG. 11 indicates an example of the opening 180 including the first recessed portion 181 in a tapered shape and the second recessed portion 183 in a tapered shape. A in FIG. 12 indicates an example of the opening 180 including the first recessed portion 181 having a curved side. B in FIG. 12 indicates an example of the opening 180 including the second recessed portion 183 having a curved side. Like the opening 180 in FIG. 10, the opening 180 can reduce the deposition of a reaction product during etching. It can be also understood that the first recessed portion 181 in A of FIG. 12 is curved at the bottom.

A configuration of the light receiving element 2 other than the aforementioned configurations is the same as the configuration of the light receiving element 2 described in the first embodiment of the present disclosure, and thus a description thereof is omitted.

As described above, the second recessed portion tapered in cross section is used for the light receiving element 2 according to the second embodiment of the present disclosure, thereby reducing the deposition of a reaction product during etching.

### 3. Third Embodiment

For the light receiving element 2 according to the first embodiment, the photoelectric conversion unit 101 is used. The photoelectric conversion unit 101 includes a photodiode that multiplies, by a reverse bias voltage, a charge generated by the photoelectric conversion of an SPAD or an APD. A light receiving element 2 according to a fourth embodiment of the present disclosure is different from that of the first embodiment in that a photoelectric conversion unit including a typical photodiode is used.

### [Configuration of Pixel in Cross Section]

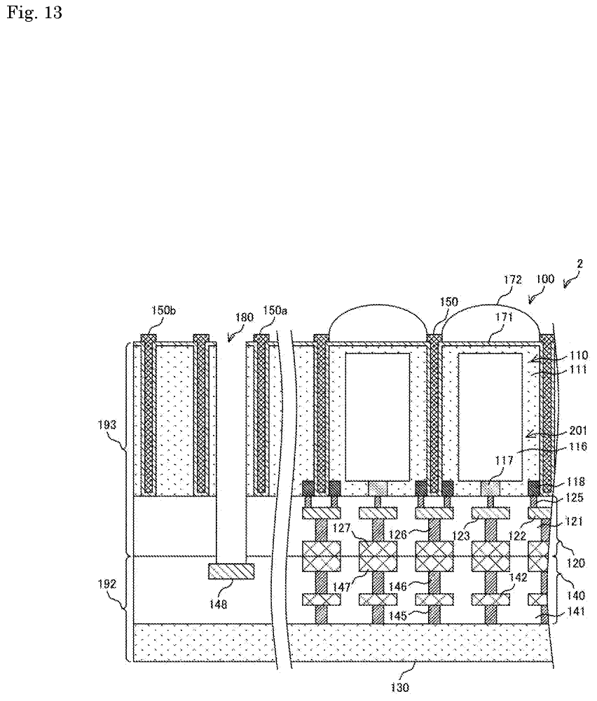

FIG. 13 is a cross-sectional view illustrating a configuration example of a pixel according to the third embodiment of the present disclosure. FIG. 13 is a cross-sectional view illustrating a configuration example of a pixel 100 as in FIG. 3. The pixel 100 is different from the pixel 100 in FIG. 3 in that a photoelectric conversion unit 201 including a photodiode is disposed.

The photoelectric conversion unit 201 in FIG. 13 includes a p-type well region 111 in a semiconductor substrate 110 and an n-type semiconductor region 116 disposed in the well region 111. A photodiode configured using a pn junction between the n-type semiconductor region 116 and the p-type well region 111 around the semiconductor region 116 corresponds to the photoelectric conversion unit 201. The well region 111 and the semiconductor region 116 constitute an anode region and a cathode region, respectively.

In the semiconductor substrate 110 of FIG. 13, a semiconductor region 117 and semiconductor regions 118 are further disposed. The semiconductor region 117 is a semiconductor region having a relatively high n-type impurity concentration and a semiconductor region that is adjacent to the semiconductor region 116 and is electrically connected thereto. A contact plug 125 is connected to the semiconductor region 117. The semiconductor region 118 is a semiconductor region having a relatively high p-type impurity concentration and a semiconductor region that is adjacent to the well region and is electrically connected thereto. The contact plug 125 is also connected to the semiconductor region 118. The semiconductor region 118 is a semiconductor region constituting a so-called well contact.

Wiring layers 122 and 123 are disposed in a wiring region 120. The wiring layer 122 is connected to the well region 111, which constitutes an anode region, via the contact plug 125 and the semiconductor region 118. The wiring layer 123 is connected to the semiconductor region 116, which constitutes a cathode region, via the contact plug 125 and the semiconductor region 117. A wiring layer 124 is omitted.

Also in a pad opening 180 of FIG. 13, a first recessed portion 181 and a second recessed portion 182 are disposed as illustrated in FIGS. 5 and 6, thereby preventing the occurrence of poor connection between an electrode pad 148 and a bonding wire.

A configuration of the light receiving element 2 other than the aforementioned configurations is the same as the configuration of the light receiving element 2 described in the first embodiment of the present disclosure, and thus a description thereof is omitted.

As described above, in the use of the photoelectric conversion unit 101 in the light receiving element 2 according to the third embodiment of the present disclosure, the pad opening 180 includes the first recessed portion 181 and the second recessed portion 182, thereby preventing the occurrence of poor connection between the electrode pad 148 and the bonding wire.

### 4. Example of Application to Ranging Device

The technique according to the present disclosure can be applied to various products. For example, the technique according to the present disclosure may be applied to a ranging device. The ranging device is a device for measuring a distance to an object.

### [Configuration of Light Receiving Element]

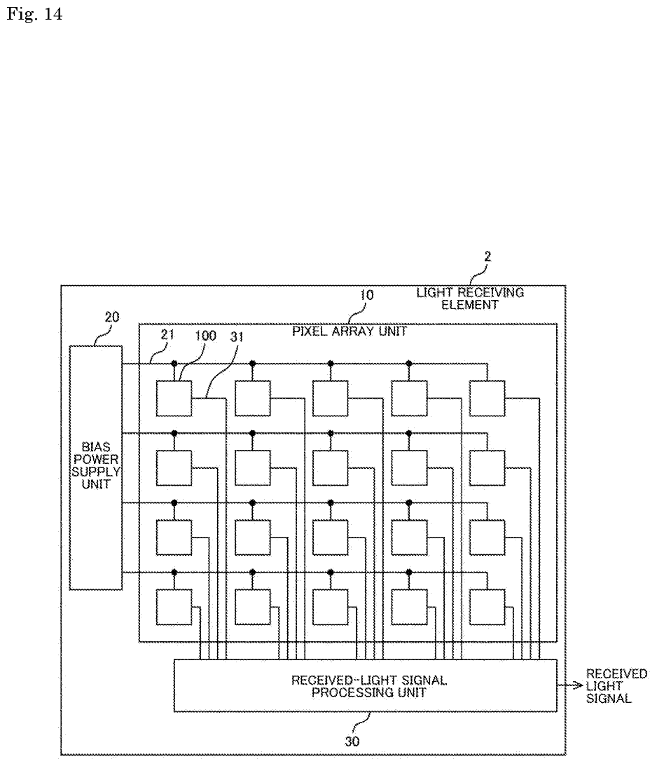

FIG. 14 is a diagram illustrating a configuration example of the light receiving element for the ranging device to which the technique according to the present disclosure is applicable. The light receiving element 2 in FIG. 14 includes a pixel array unit 10, a bias power supply unit 20, and a received-light signal processing unit 30.

The pixel array unit 10 is configured with the pixels 100 disposed in a two-dimensional lattice form, the pixel 100 including a photoelectric conversion unit for photoelectric conversion of incident light. The pixel 100 detects incident light and outputs a received light signal as a detection result. For the photoelectric conversion unit, for example, an APD or an SPAD can be used. Hereinafter it is assumed that the pixel 100 includes an SPAD disposed as the photoelectric conversion unit. Signal lines 21 and 31 are connected to each of the pixels 100. The signal line 21 is a signal line that supplies a bias voltage of the pixel 100. The signal line 31 is a signal line that transmits a received light signal from the pixel 100. The pixel array unit 10 of FIG. 14 illustrates an example in which the pixels 100 are placed in four rows and five columns. The number of pixels 100 disposed in the pixel array unit 10 is not limited thereto.

The bias power supply unit 20 is a power supply that supplies a bias voltage to the pixels 100. The bias power supply unit 20 supplies a bias voltage via the signal lines 21.

The received-light signal processing unit 30 processes the received light signals outputted from the plurality of pixels 100 disposed in the pixel array unit 10. The processing of the received-light signal processing unit 30 corresponds to, for example, the processing of detecting a distance to an object on the basis of incident light detected by the pixel 100. Specifically, the received-light signal processing unit 30 can perform ToF (Time of Flight)-type distance detection that is used when measuring a distance to a remote object in an imaging device such as an onboard camera. In this distance detection, a distance is detected by irradiating the object with light from a light source disposed in the imaging device, detecting light reflected from the object, and measuring the time for the light from the light source to reciprocate between the object and the light source. An SPAD capable of detecting light at a high speed is used as a device for the distance detection. The received-light signal processing unit 30 is an example of a processing circuit described in the claims.

The circuit configuration of the pixel 100 disposed in the pixel array unit 10 according to the foregoing embodiment will be described below.

### [Pixel Configuration]

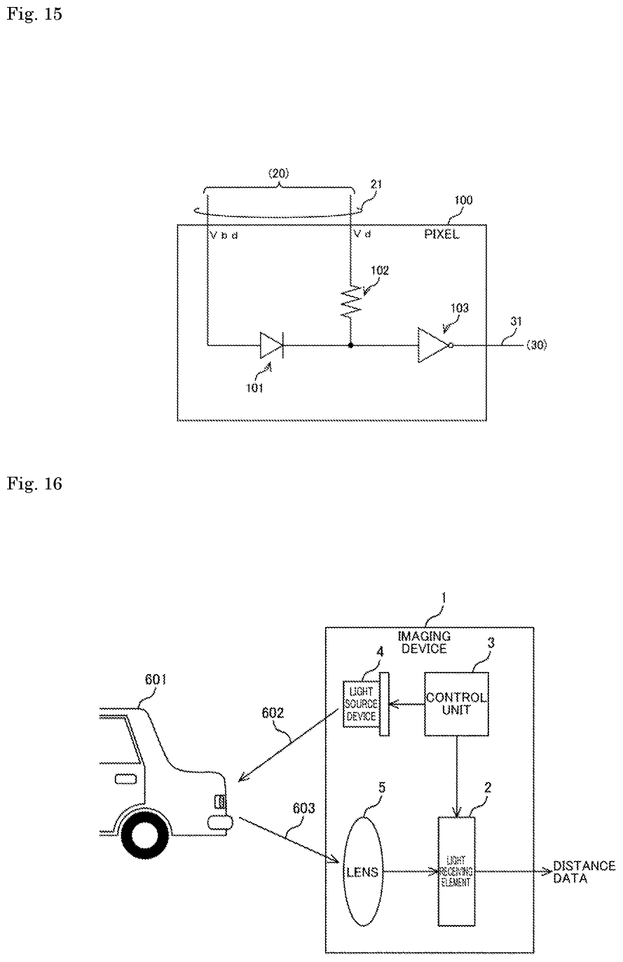

FIG. 15 is a circuit diagram illustrating a configuration example of the pixel for the ranging device to which the technique according to the present disclosure is applicable. FIG. 15 is a circuit diagram illustrating a configuration example of the pixel 100 illustrated in FIG. 14. The pixel 100 in FIG. 15 includes a photoelectric conversion unit 101, a resistor 102, and an inverting buffer 103. The signal line 21 in FIG. 15 includes a signal line Vbd to which a breakdown voltage of the photoelectric conversion unit 101 is applied and a signal line Vd that supplies power for detecting a breakdown state of the photoelectric conversion unit 101.

The anode of the photoelectric conversion unit 101 is connected to the signal line Vbd. The cathode of the photoelectric conversion unit 101 is connected to one end of the resistor 102 and the input of the inverting buffer 103. The other end of the resistor 102 is connected to the signal line Vd. The output of the inverting buffer 103 is connected to the signal line 31.

In the photoelectric conversion unit 101 of FIG. 15, a reverse bias voltage is applied by the signal line Vbd and the signal line Vd.

The resistor 102 is a resistor for performing quenching. The quenching is processing for returning the photoelectric conversion unit 101 in the breakdown state to a steady state. When the photoelectric conversion unit 101 is placed in a breakdown state by a multiplication caused by incident light, a rapid reverse current passes through the photoelectric conversion unit 101. The reverse current increases the terminal voltage of the resistor 102. Since the resistor 102 is connected in series with the photoelectric conversion unit 101, a voltage drop is generated by the resistor 102 and causes the terminal voltage of the photoelectric conversion unit 101 to fall below a voltage where the breakdown state can be maintained. Thus, the photoelectric conversion unit 101 can be returned from the breakdown state to a steady state. The resistor 102 can be replaced with a constant current circuit including a MOS transistor.

The inverting buffer 103 is a buffer that shapes a pulse signal based on the transition and return of the photoelectric conversion unit 101 to the breakdown state. Due to the inverting buffer 103, a received light signal based on a current passing through the photoelectric conversion unit 101 is generated according to radiated light and is outputted to the signal line 31.

### [Configuration of Imaging Device]

FIG. 16 is a diagram illustrating a configuration example of an imaging device for the ranging device to which the technique according to the present disclosure is applicable. FIG. 16 is a block diagram illustrating a configuration example of an imaging device 1 constituting the ranging device. The imaging device 1 in FIG. 16 includes the light receiving element 2, a control unit 3, a light source device 4, and a lens 5. FIG. 16 illustrates an object 601 of distance measurement.

The lens 5 is a lens for forming an image of an object on the light receiving element 2. The light receiving element 2 illustrated in FIG. 10 can be used as the light receiving element 2 in FIG. 16.

The light source device 4 emits light to an object of distance measurement. For example, a laser light source that emits infrared light can be used as the light source device 4.

The control unit 3 controls the overall imaging device 1. Specifically, the control unit 3 controls the light source device 4 to emit an outgoing beam 602 to the object 601 and notifies the light receiving element 2 of the start of emission. The light receiving element 2 notified of the emission of the outgoing beam 602 detects a reflected ray 603 from the object 601, measures a time from the emission of the outgoing beam 602 to the detection of the reflected ray 603, and measures a distance to the object 601. The measured distance is outputted as distance data to the outside of the imaging device 1. The imaging device 1 is an example of an electronic device described in the claims.

### 5. Example of Application to DVS

The technique according to the present disclosure can be applied to various products. For example, the technique according to the present disclosure may be applied to a dynamic vision sensor (DVS). The DVS is an imaging device that outputs information on a pixel having a changed luminance.

### [Configuration of Light Receiving Element]

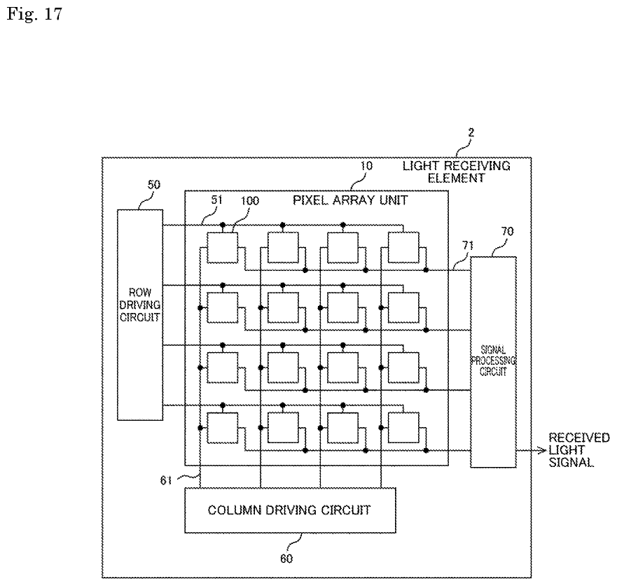

FIG. 17 is a diagram illustrating a configuration example of the light receiving element for a DVS to which the technique according to the present disclosure is applicable. The light receiving element 2 in FIG. 17 includes the pixel array unit 10, a row driving circuit 50, a column driving circuit 60, and a signal processing circuit 70.

The pixel array unit 10 is configured with the pixels 100 disposed in a two-dimensional lattice form, the pixel 100 including a photoelectric conversion unit for photoelectric conversion of incident light. The pixel 100 detects incident light and outputs a detection signal if the detected incident light changes. Hereinafter it is assumed that a photodiode is disposed as the photoelectric conversion unit in the pixel 100. Signal lines 51, 61, and 71 are connected to each of the pixels 100. The signal line 51 is a signal line for transmitting a row driving signal. The signal line 51 is a signal line for transmitting a column driving signal. The signal line 71 is a signal line for transmitting the detection signal from the pixel 100. The pixel array unit 10 of FIG. 17 illustrates an example in which the pixels 100 are placed in four rows and four columns. The number of pixels 100 disposed in the pixel array unit 10 is not limited thereto.

The row driving circuit 50 selects a row address of the pixel array unit 10 and causes the pixel 100 corresponding to the selected row address to output a detection signal. The row driving circuit 50 outputs a control signal (row driving signal) to the signal line 51.

The column driving circuit 60 selects a column address of the pixel array unit 10 and causes the pixel 100 corresponding to the selected column address to output a detection signal. The column driving circuit 60 outputs a control signal (column driving signal) to the signal line 61.

The signal processing circuit 70 performs predetermined signal processing on the detection signal from the pixel 100. The signal processing circuit 70 associates the detection signal with the array of the pixels 100 of the pixel array unit 10 to generate two-dimensional image data and then performs image recognition or the like. The signal processing circuit 70 is an example of a processing circuit described in the

### [Pixel Configuration]

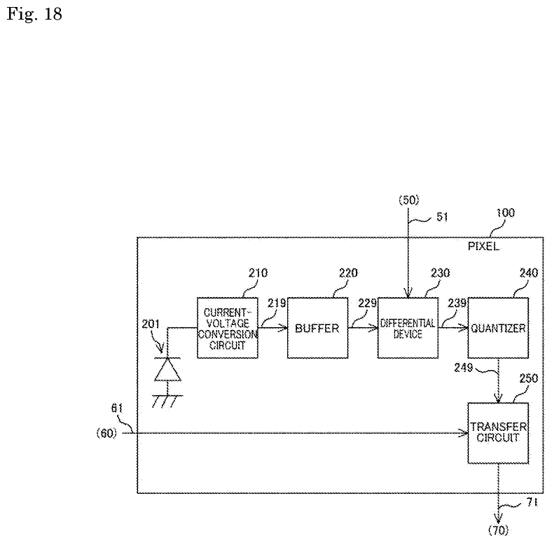

FIG. 18 is a diagram illustrating a configuration example of the pixel for a DVS to which the technique according to the present disclosure is applicable. The pixel 100 in FIG. 18 includes the photoelectric conversion unit 201, a current-voltage conversion circuit 210, a buffer 220, a differential device 230, a quantizer 240, and a transfer circuit 250.

The photoelectric conversion unit 201 detects incident light. The photoelectric conversion unit 201 outputs a sink current, which corresponds to incident light, to the current-voltage conversion circuit 210 of the subsequent stage.

The current-voltage conversion circuit 210 is a circuit that converts an output current from the photoelectric conversion unit 201 into a voltage. During the conversion, logarithmic compression is performed and a compressed voltage signal is outputted to the buffer 220.

The buffer 220 is a buffer that amplifies the voltage signal of the current-voltage conversion circuit 210 and outputs the signal to the differential device 230 of the subsequent stage.

The differential device 230 detects a difference of the voltage signal outputted from the buffer 220, so that a change of the voltage signal is detected. The differential device 230 starts detecting the change of the voltage signal after the row driving signal is inputted from the row driving circuit 50. The detected change of the voltage signal is outputted through a signal line 239.

The quantizer 240 quantizes the voltage signal from the differential device 230 and outputs the signal as a detection signal. The detection signal is outputted through a signal line 249.

The transfer circuit 250 is a circuit that outputs the detection signal to the signal processing circuit 70 on the basis of the column driving signal from the column driving circuit 60.

### [Configuration of Current-Voltage Conversion Circuit]

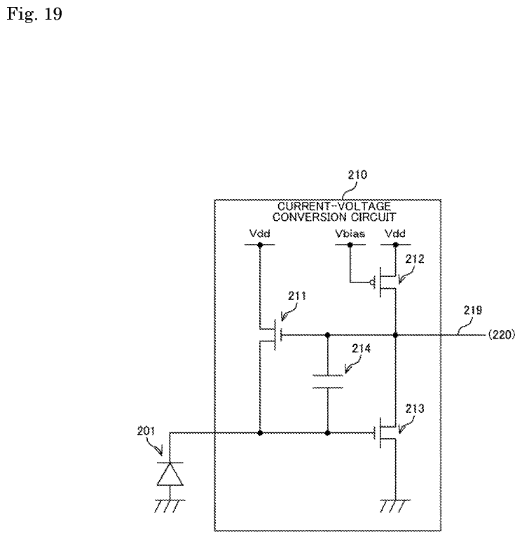

FIG. 19 is a diagram illustrating a configuration example of the current-voltage conversion circuit for a DVS to which the technique according to the present disclosure is applicable. FIG. 19 is a circuit diagram illustrating a configuration example of the current-voltage conversion circuit 210. The current-voltage conversion circuit 210 of FIG. 19 includes MOS transistors 211 to 213 and a capacitor 214. As the MOS transistors 211 and 213, n-channel MOS transistors can be used. As the MOS transistor 212, a p-channel MOS transistor can be used. Furthermore, a power supply line Vdd and a power supply line Vbias are disposed in the current-voltage conversion circuit 210 of FIG. 19. The power supply line Vdd is a power supply line for supplying power to the current-voltage conversion circuit 210. The power supply line Vbias is a power supply line for supplying a bias voltage. FIG. 19 also illustrates the photoelectric conversion unit 201.

The anode of the photoelectric conversion unit 201 is grounded, and the cathode of the photoelectric conversion unit 201 is connected to the source of the MOS transistor 211, the gate of the MOS transistor 213, and one end of the capacitor 214. The other end of the capacitor 214 is connected to the gate of the MOS transistor 211, the drain of the MOS transistor 212, the drain of the MOS transistor 213, and a signal line 219. The source of the MOS transistor 211 is connected to the power supply line Vdd, and the source of the MOS transistor 213 is grounded. The gate of the MOS transistor 212 is connected to the power supply line Vbias, and the source thereof is connected to the power supply line Vdd.

The MOS transistor 211 is a MOS transistor that supplies current to the photoelectric conversion unit 201. A sink current corresponding to incident light passes through the photoelectric conversion unit 201. The MOS transistor 211 supplies the sink current. At this point, the gate of the MOS transistor 211 is driven by the output voltage of the MOS transistor 213, which will be described later, and outputs a source current equal to the sink current of the photoelectric conversion unit 201. A gate-source voltage Vgs of the MOS transistor corresponds to a source current, so that the source voltage of the MOS transistor corresponds to the current of the photoelectric conversion unit 201. Thus, the current of the photoelectric conversion unit 201 is converted into a voltage signal.

The MOS transistor 213 is a MOS transistor that amplifies the source voltage of the MOS transistor 211. The MOS transistor 212 constitutes the constant current load of the MOS transistor 213. An amplified voltage signal is outputted to the drain of the MOS transistor 213. The voltage signal is outputted to the signal line 219 and is returned to the gate of the MOS transistor 211. When Vgs of the MOS transistor 211 is equal to or lower than a threshold voltage, a source current exponentially changes relative to a change of Vgs. Thus, the output voltage of the MOS transistor 213, that is, an output voltage to be returned to the gate of the MOS transistor 211 corresponds to a voltage signal obtained by logarithmic compression on the output current of the photoelectric conversion unit 201, the output current being equal to the source current of the MOS transistor 211.

The capacitor 214 is a capacitor for phase compensation. The capacitor 214 is connected between the drain and the gate of the MOS transistor 213 and performs phase compensation on the MOS transistor 213 constituting an amplifier circuit.

### [Configuration of Differential Device and Quantizer]

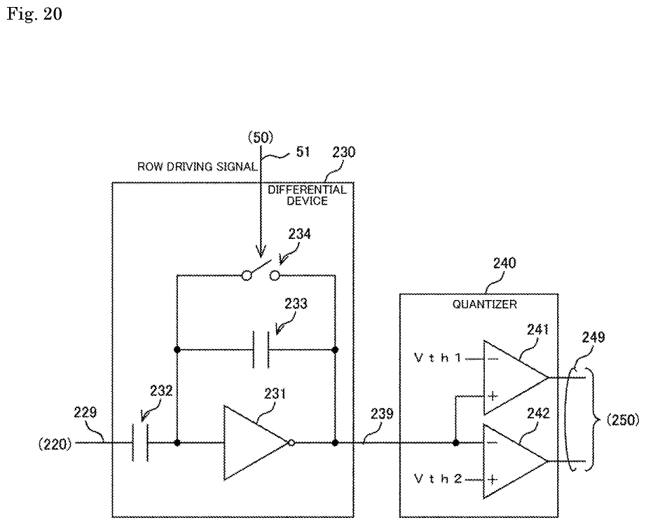

FIG. 20 is a diagram illustrating a configuration example of the differential device and the quantizer for a DVS to which the technique according to the present disclosure is applicable. FIG. 20 is a circuit diagram illustrating a configuration example of the differential device 230 and the quantizer 240.

The differential device 230 of FIG. 20 includes an inverting amplifier 231, capacitors 232 and 233, and a switch 234.

The capacitor 232 is connected between the signal line 229 and the input of the inverting amplifier 231. The output of the inverting amplifier 231 is connected to the signal line 239. The capacitor 233 and the switch 234, which are connected in parallel, are connected between the input and the output of the inverting amplifier 231. The control input of the switch 234 is connected to the signal line 51.

The capacitor 232 is a coupling capacitor that removes a direct-current component of a voltage signal outputted from the buffer 220. A signal corresponding to the change of the voltage signal is transmitted by the capacitor 232.

The inverting amplifier 231 is an amplifier that charges the capacitor 233 according to the change of the voltage signal transmitted by the capacitor 232. The inverting amplifier 231 and the capacitor 232 constitute an integrating circuit and integrate the change of the voltage signal transmitted by the capacitor 232.

The switch 234 is a switch that discharges the capacitor 233. The switch 234 is brought into conduction to discharge the capacitor 232 and resets the change of the voltage signal to 0 V, the change being integrated by the capacitor 232. The switch 234 is controlled by the row driving signal transmitted by the signal line 51.

The differential device 230 integrates the change of the voltage signal and outputs the integrated change, the change corresponding to incident light in a period after a reset in response to the row driving signal. Thus, the influence of noise can be reduced.

The quantizer 240 includes comparators 241 and 242. The signal line 239 is connected to the non-inverting input of the comparator 241 and the inverting input of the comparator 242. A predetermined threshold voltage Vth1 is applied to the inverting input of the comparator 241, and a predetermined threshold voltage Vth2 is applied to the non-inverting input of the comparator 242. The outputs of the comparators 241 and 242 each constitute the signal line 249.

The comparator 241 compares the threshold voltage Vth1 and an output voltage from the differential device 230. A value “1” is outputted when the output voltage from the differential device 230 is higher than the threshold voltage Vth1.

The comparator 242 compares the threshold voltage Vth2 and an output voltage from the differential device 230. A value “1” is outputted when the output voltage from the differential device 230 is lower than the threshold voltage Vth2.

The threshold voltage Vth1 is set at a threshold voltage higher than an output voltage determined when the differential device 230 is reset, and the threshold voltage Vth2 is set at a threshold voltage lower than an output voltage determined when the differential device 230 is reset. Thus, a change can be detected in both directions: an increase and a reduction of the output signal of the photoelectric conversion unit 201. The comparators 241 and 242 binarize and quantize an output voltage from the differential device 230.

A signal quantized by the quantizer 240 is inputted to the transfer circuit 250. In response to the input of a signal with a value “1”, the transfer circuit 250 can transfer a change of an incident light amount as a detection signal to the signal processing circuit 70, the change exceeding a predetermined threshold. When the detection signal is transferred by the transfer circuit 250, the signal processing circuit 70 retains the transfer of the signal as an address event, causes the row driving unit 50 to output a row driving signal to the pixel 100, and resets the differential device 230. Thus, in the pixel 100 where the address event occurs, an integration of a change of the voltage signal according to incident light is restarted.

### [Configuration of Imaging Device]

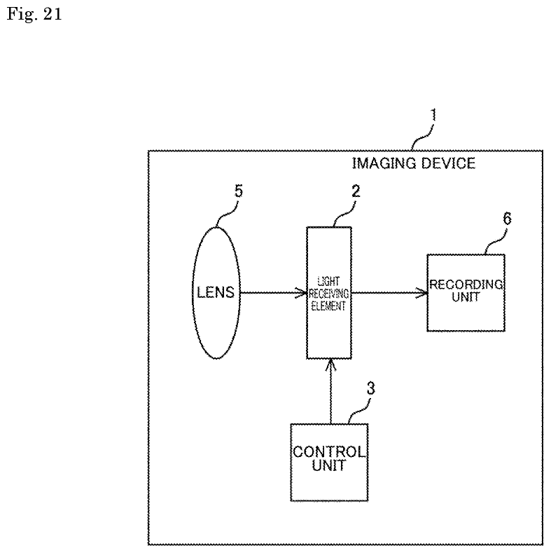

FIG. 21 is a diagram illustrating a configuration example of the imaging device for a DVS to which the technique according to the present disclosure is applicable. FIG. 21 is a block diagram illustrating a configuration example of the imaging device 1 constituting the DVS. The imaging device 1 in FIG. 21 includes the light receiving element 2, the control unit 3, the lens 5, and a recording unit 6.

The lens 5 is a lens for forming an image of an object on the light receiving element 2. The light receiving element 2 illustrated in FIG. 15 can be used as the light receiving element 2 in FIG. 21.

The control unit 3 controls the light receiving element 2 to capture an image of image data. The recording unit 6 records the image data from the light receiving element 2.

The light receiving element 2 can detect a region having a changed luminance by obtaining the pixel 100 where an address event is detected. Image data is generated while being updated only in the region, enabling imaging at high speeds. The imaging device 1 is an example of an electronic device described in the claims

The light receiving element 2 according to the second embodiment may be combined with the light receiving element 2 according to the third embodiment. Specifically, the configuration of the pad openings 180 in FIG. 10 may be applied to the pixel 100 in FIG. 13.

Finally, the descriptions of the above-described embodiments are merely examples of the present disclosure, and the present disclosure is not limited to the above-described embodiments. Therefore, it goes without saying that various changes aside from the above-described embodiments can be made according to the design and the like within a scope that does not depart from the technical spirit of the present disclosure.

Additionally, the effects described in the present specification are merely exemplary and are not limited. Other effects may be obtained as well.

In addition, the drawings in the above-described embodiments are schematic, and dimensional ratios and the like of respective parts are not necessarily consistent with actual ones. Furthermore, the drawings of course include parts where dimensional relationships and ratios differ among drawings.

The present technique can also have the following configurations.

(1) A light receiving element including: a wiring region disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light;

an electrode pad that is disposed in the wiring region and is connected to the wiring layer so as to be electrically connected to the outside;

a first recessed portion that is formed on the back side of the semiconductor substrate, the back side being opposed to the front side of the semiconductor substrate, the first recessed portion having the bottom near the front side of the semiconductor substrate and near the electrode pad; and

a second recessed portion that is formed on the front side of the first recessed portion and has the bottom formed on a surface of the electrode pad.

(2) The light receiving element according to (1), wherein the second recessed portion is configured with a different opening size from the first recessed portion.

(3) The light receiving element according to (2), wherein on the back side of the semiconductor substrate, the second recessed portion has a different opening area from the first recessed portion in plan view.

(4) The light receiving element according to (2), wherein on the front side of the semiconductor substrate, the second recessed portion has a different opening area from the first recessed portion in plan view.

(5) The light receiving element according to (2), wherein the second recessed portion has an opening area and a bottom area that are different from each other.

(6) The light receiving element according to (5), wherein the second recessed portion has a larger shape on the back side of the semiconductor substrate than on the bottom side of the second recessed portion.

(7) The light receiving element according to (6), wherein the second recessed portion is tapered in cross section.

(8) The light receiving element according to (7), wherein the second recessed portion has a plurality of tapered shapes with different tilt angles in cross section.

(9) The light receiving element according to any one of (1) to (8), wherein the first recessed portion has an opening area and a bottom area that are different from each other.

(10) The light receiving element according to (9), wherein the first recessed portion has a larger shape on the back side of the semiconductor substrate than on the bottom side of the first recessed portion.

(11) The light receiving element according to (10), wherein the first recessed portion is tapered in cross section.

(12) The light receiving element according to any one of (1) to (11), wherein the first recessed portion is configured with a vertical wall surface.

(13) The light receiving element according to any one of (1) to (11), wherein the first recessed portion is configured with a curved side.

(14) The light receiving element according to any one of (1) to (13), wherein the first recessed portion has a bottom linearly shaped in cross section.

(15) The light receiving element according to any one of (1) to (13), wherein the first recessed portion is configured with a curved bottom.

(16) The light receiving element according to any one of (1) to (15), wherein a reaction product is deposited in the first recessed portion during etching.

(17) The light receiving element according to any one of (1) to (16), wherein the photoelectric conversion unit includes a photodiode.

(18) The light receiving element according to (16), wherein the photoelectric conversion unit includes the photodiode that multiplies, by a high reverse bias voltage, a charge generated by the photoelectric conversion of incident light.

(19) The light receiving element according to (18), wherein the photoelectric conversion unit allows the multiplication on the generated charge at a pn junction including a p-type semiconductor region and an n-type semiconductor region.

(20) The light receiving element according to (19), wherein the photoelectric conversion unit has a cathode region including the n-type semiconductor region.

(21) The light receiving element according to (20), wherein the photoelectric conversion unit has the cathode region disposed on the front side of the semiconductor substrate.

(22) The light receiving element according to (19), wherein the photoelectric conversion unit has an anode region disposed on the front side of the semiconductor substrate.

(23) A light receiving element including: a wiring region disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light;

an electrode pad that is disposed in the wiring region and is connected to the wiring layer so as to be electrically connected to the outside;

a first recessed portion that is formed on the back side of the semiconductor substrate and has a bottom not so deep as to reach the electrode pad; and

a second recessed portion configured with a bottom reaching the electrode pad from the bottom of the first recessed portion.

(24) An electronic device including: a wiring region disposed next to the front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light;

an electrode pad that is disposed in the wiring region and is connected to the wiring layer so as to be electrically connected to the outside;

a first recessed portion that is formed on the back side of the semiconductor substrate, the back side being opposed to the front side of the semiconductor substrate, the first recessed portion having the bottom near the front side of the semiconductor substrate and near the electrode pad;

a second recessed portion that is formed on the front side of the first recessed portion and has the bottom formed on a surface of the electrode pad; and

a processing circuit that processes a signal generated on the basis of the photoelectric conversion.

(25) The electronic device according to (24), wherein the photoelectric conversion unit performs photoelectric conversion on the incident light that is emitted from a light source, is reflected from a subject, and enters the photoelectric conversion unit, and

the processing circuit performs the processing of measuring a distance to the subject by measuring a time from the light emission from the light source to the generation of the signal.

(26) The electronic device according to (24), wherein the processing circuit performs the processing of detecting a change of the signal.

(27) The electronic device according to (26), wherein the processing circuit detects the change by comparison with a predetermined threshold value.

(28) The electronic device according to (24), wherein the processing circuit is disposed on another semiconductor substrate bonded to the semiconductor substrate.

### REFERENCE SIGNS LIST

1 Imaging device
2 Light receiving element
10 Pixel array unit
30 Received-light signal processing unit
70 Signal processing circuit
100 Pixel
101, 201 Photoelectric conversion unit
110, 130 Semiconductor substrate
120, 140 Wiring region
121, 141 Insulating layer
122, 123, 124, 142 Wiring layer
126, 146 Via plug
127, 147 Pad
128, 148 Electrode pad
180 Pad opening
181 First recessed portion
182, 183, 184 Second recessed portion

1. A light receiving element comprising: a wiring region disposed next to a front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light;
an electrode pad that is disposed in the wiring region and is connected to the wiring layer so as to be electrically connected to outside;
a first recessed portion that is formed on a back side of the semiconductor substrate, the back side being opposed to the front side of the semiconductor substrate, the first recessed portion having a bottom near the front side of the semiconductor substrate and near the electrode pad; and
a second recessed portion that is formed on the front side of the first recessed portion and has a bottom formed on a surface of the electrode pad.

2. The light receiving element according to claim 1, wherein the second recessed portion is configured with a different opening size from the first recessed portion.

3. The light receiving element according to claim 2, wherein on the back side of the semiconductor substrate, the second recessed portion has a different opening area from the first recessed portion in plan view.

4. The light receiving element according to claim 2, wherein on the front side of the semiconductor substrate, the second recessed portion has a different opening area from the first recessed portion in plan view.

5. The light receiving element according to claim 2, wherein the second recessed portion has an opening area and a bottom area that are different from each other.

6. The light receiving element according to claim 5, wherein the second recessed portion has a larger shape on the back side of the semiconductor substrate than on the bottom side of the second recessed portion.

7. The light receiving element according to claim 6, wherein the second recessed portion is tapered in cross section.

8. The light receiving element according to claim 7, wherein the second recessed portion has a plurality of tapered shapes with different tilt angles in cross section.

9. The light receiving element according to claim 1, wherein the first recessed portion has an opening area and a bottom area that are different from each other.

10. The light receiving element according to claim 9, wherein the first recessed portion has a larger shape on the back side of the semiconductor substrate than on the bottom side of the first recessed portion.

11. The light receiving element according to claim 10, wherein the first recessed portion is tapered in cross section.

12. The light receiving element according to claim 1, wherein the first recessed portion is configured with a vertical wall surface.

13. The light receiving element according to claim 1, wherein the first recessed portion is configured with a curved side.

14. The light receiving element according to claim 1, wherein the first recessed portion has a bottom linearly shaped in cross section.

15. The light receiving element according to claim 1, wherein the first recessed portion is configured with a curved bottom.

16. The light receiving element according to claim 1, wherein a reaction product is deposited in the first recessed portion during etching.

17. The light receiving element according to claim 1, wherein the photoelectric conversion unit includes a photodiode.

18. The light receiving element according to claim 17, wherein the photoelectric conversion unit includes the photodiode that multiplies, by a high reverse bias voltage, a charge generated by the photoelectric conversion of incident light.

19. The light receiving element according to claim 18, wherein the photoelectric conversion unit allows the multiplication on the generated charge at a pn junction including a p-type semiconductor region and an n-type semiconductor region.

20. The light receiving element according to claim 19, wherein the photoelectric conversion unit has a cathode region including the n-type semiconductor region.

21. The light receiving element according to claim 20, wherein the photoelectric conversion unit has the cathode region disposed on the front side of the semiconductor substrate.

22. The light receiving element according to claim 19, wherein the photoelectric conversion unit has an anode region disposed on the front side of the semiconductor substrate.

23. A light receiving element comprising: a wiring region disposed next to a front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light;
an electrode pad that is disposed in the wiring region and is connected to the wiring layer so as to be electrically connected to outside;
a first recessed portion that is formed on a back side of the semiconductor substrate and has a bottom not so deep as to reach the electrode pad; and
a second recessed portion configured with a bottom reaching the electrode pad from the bottom of the first recessed portion.

24. An electronic device comprising: a wiring region disposed next to a front side of a semiconductor substrate, the wiring region including a wiring layer for transmitting a signal and an insulating layer for insulating the wiring layer, the wiring layer being connected to a photoelectric conversion unit that is disposed in the semiconductor substrate and performs photoelectric conversion on incident light;
an electrode pad that is disposed in the wiring region and is connected to the wiring layer so as to be electrically connected to outside;
a first recessed portion that is formed on a back side of the semiconductor substrate, the back side being opposed to the front side of the semiconductor substrate, the first recessed portion having a bottom near the front side of the semiconductor substrate and near the electrode pad; and
a second recessed portion that is formed on the front side of the first recessed portion and has a bottom formed on a surface of the electrode pad; and
a processing circuit that processes a signal generated on a basis of the photoelectric conversion.

25. The electronic device according to claim 24, wherein the photoelectric conversion unit performs photoelectric conversion on the incident light that is emitted from a light source, is reflected from a subject, and enters the photoelectric conversion unit, and
the processing circuit performs the processing of measuring a distance to the subject by measuring a time from the light emission from the light source to the generation of the signal.

26. The electronic device according to claim 24, wherein the processing circuit performs the processing of detecting a change of the signal.

27. The electronic device according to claim 26, wherein the processing circuit detects the change by comparison with a predetermined threshold value.

28. The electronic device according to claim 24, wherein the processing circuit is disposed on another semiconductor substrate bonded to the semiconductor substrate.
